(19) United States
(12) Patent Application Publication
(10) Pub. No.: US 2012/0061794 A1
(43) Pub. Date: Mar. 15, 2012

(54) METHODS OF FORMING THROUGH WAFER INTERCONNECTS IN SEMICONDUCTOR STRUCTURES USING SACRIFICIAL MATERIAL, AND SEMICONDUCTOR STRUCTURES FORMED BY SUCH METHODS

(75) Inventor: Mariam Sadaka, Austin, TX (US)

(73) Assignee: S.O.I. TEC SILICON ON INSULATOR TECHNOLOGIES, Bernin (FR)

(21) Appl. No.: 12/879,637

(22) Filed: Sep. 10, 2010

(51) Int. Cl. H01L 21/768; H01L 23/52; H01L 21/30

(52) U.S. Cl. 257/503; 438/667; 438/458; 257/E21.597; 257/E21.211; 257/E23.141

(57) ABSTRACT

Methods of fabricating semiconductor structures include providing a sacrificial material within a via recess, forming a first portion of a through wafer interconnect in the semiconductor structure, and replacing the sacrificial material with conductive material to form a second portion of the through wafer interconnect. Semiconductor structures are formed by such methods. For example, a semiconductor structure may include a sacrificial material within a via recess, and a first portion of a through wafer interconnect that is aligned with the via recess. Semiconductor structures include through wafer interconnects comprising two or more portions having a boundary therebetween.

### TECHNICAL FIELD

The present invention generally relates to methods of forming semiconductor structures that include through wafer interconnects, and to semiconductor structures formed by such methods.

### BACKGROUND

Semiconductor structures include, and are formed during the fabrication of, devices that employ semiconductor materials (i.e., semiconductor devices) such as electronic signal processors, memory devices, photoelectric devices (e.g., light emitting diodes (LEDs), laser diodes, solar cells, etc.), micro- and nano-electromechanical devices, etc. In such semiconductor structures, it is often necessary or desirable to electrically and/or structurally couple one semiconductor structure to another device or structure (e.g., another semiconductor structure). Such processes in which semiconductor structures are coupled to another device or structure are often referred to as three-dimensional (3D) integration processes.

The 3D integration of two or more semiconductor structures can produce a number of benefits to microelectronic applications. For example, 3D integration of microelectronic components can result in improved electrical performance and power consumption while reducing the area of the device foot print. See, for example, P. Garrou, et al. “The Handbook of 3D Integration,” Wiley-VCH (2008).

The 3D integration of semiconductor structures may take place by the attachment of a semiconductor die to one or more additional semiconductor dice (i.e., die-to-die (D2D)), a semiconductor die to one or more semiconductor wafers (i.e., die-to-wafer (D2W)), as well as a semiconductor wafer to one or more additional semiconductor wafers (i.e., wafer-to-wafer (W2W)), or a combination thereof.

Often, the individual semiconductor dice or wafers may be relatively thin and difficult to handle with equipment for processing the dice or wafers. Thus, so-called “carrier” dice or wafers may be attached to the actual dice or wafers that include therein the active and passive components of operative semiconductor devices. The carrier dice or wafers do not typically include any active or passive components of a semiconductor device to be formed. Such carrier dice and wafers are referred to herein as “carrier substrates.” The carrier substrates increase the overall thickness of the dice or wafers and facilitate handling of the dice or wafers by processing equipment used to process the active and/or passive components in the dice or wafers attached thereto that will include the active and passive components of a semiconductor device to be fabricated thereon.

It is known to employ what are referred to herein as “through wafer interconnects” or “TWIs” for establishing electrical connections between active components in a semiconductor structure and conductive features of another device or structure to which the semiconductor structure is attached. Through wafer interconnects are conductive vias that extend through at least a portion of a semiconductor structure.

### BRIEF SUMMARY

In some embodiments, the present invention includes methods of fabricating a semiconductor structure. A sacrificial material may be provided within at least one via recess extending partially through a semiconductor structure. A first portion of at least one through wafer interconnect may be formed in the semiconductor structure. The first portion of the at least one through wafer interconnect may be aligned with the at least one via recess. The sacrificial material within the at least one via recess may be replaced with conductive material to form a second portion of the at least one through wafer interconnect that is in electrical contact with the first portion of the at least one through wafer interconnect.

The present invention also includes additional embodiments of methods of fabricating semiconductor structures. In accordance with such methods, a sacrificial material is provided within at least one via recess extending into a surface of a semiconductor structure. A layer of semiconductor material may be provided over the surface of the semiconductor structure, and at least one device structure may be fabricated using the layer of semiconductor material. A first portion of at least one through wafer interconnect is formed that extends through the layer of semiconductor material. The semiconductor structure may be thinned from a side thereof opposite the layer of semiconductor material. The sacrificial material may be removed from within the at least one via recess in the semiconductor structure, and the first portion of the at least one through wafer interconnect may be exposed within the via recess; conductive material may be provided within the via recess to form a second portion of the at least one through wafer interconnect.

In yet further embodiments, the present invention includes semiconductor structures formed by methods disclosed herein. For example, in some embodiments, a semiconductor structure includes a sacrificial material within at least one via recess extending partially through a semiconductor structure from a surface of the semiconductor structure, a semiconductor material disposed over the surface of the semiconductor structure, and at least one device structure comprising at least a portion of the semiconductor material that is disposed over the surface of the semiconductor structure. A first portion of at least one through wafer interconnect extends through the semiconductor material disposed over the surface of the semiconductor structure, and the first portion of the at least one through wafer interconnect is aligned with the at least one via recess.

In additional embodiments, the present invention includes semiconductor structures comprising an active surface, a back surface, at least one transistor located within the semiconductor structure between the active surface and the back surface, and at least one through wafer interconnect extending at least partially through the semiconductor structure from at least one of the active surface and the back surface. The at least one through wafer interconnect includes a first portion, a second portion, and an identifiable boundary between a microstructure of the first portion and a microstructure of the second portion.

### BRIEF DESCRIPTION OF THE SEVERAL VIEWS OF THE DRAWINGS

While the specification concludes with claims particularly pointing out and distinctly claiming what are regarded as embodiments of the invention, the advantages of embodiments of the invention may be more readily ascertained from the description of certain examples of embodiments of the invention when read in conjunction with the accompanying drawings, in which:

FIG. 1 is a simplified cross-sectional side view of a portion of a semiconductor structure;

FIG. 2 is a simplified cross-sectional side view of a portion of another semiconductor structure that may be formed by providing via recesses partially through the semiconductor structure of FIG. 1;

FIG. 3 is a simplified cross-sectional side view of a portion of another semiconductor structure that may be formed by providing a dielectric material on or over exposed surfaces of the semiconductor structure of FIG. 2 within the via recesses therein;

FIG. 4 is a simplified cross-sectional side view of a portion of another semiconductor structure that may be formed by providing a material such as polysilicon within the via recesses of the semiconductor structure of FIG. 3;

FIG. 5 is a simplified cross-sectional side view of a portion of a bonded semiconductor structure that may be formed by bonding another semiconductor structure to the semiconductor structure of FIG. 4;

FIG. 6 is a simplified cross-sectional side view of a portion of another semiconductor structure that may be formed by thinning the another semiconductor structure in the bonded semiconductor structure of FIG. 5;

FIG. 7 is an enlarged view of a portion of another semiconductor structure that may be formed by fabricating transistors and shallow trench isolation structures in and/or on the bonded semiconductor structure of FIG. 6;

FIG. 8 is an enlarged view of a portion of another semiconductor structure that may be formed by providing a layer of dielectric material over the semiconductor structure of FIG. 7, and by providing portions of through wafer interconnects through the semiconductor structure;

FIG. 9 is an enlarged view of a portion of another semiconductor structure that may be formed by fabricating one or more layers including electrically conductive structures over a surface of the semiconductor structure of FIG. 8;

FIG. 10 is an enlarged view of a portion of another semiconductor structure that may be formed by bonding the semiconductor structure of FIG. 9 to a carrier substrate;

FIG. 11 is an enlarged view of a portion of another semiconductor structure that may be formed by removing polysilicon material from within via recesses of the semiconductor structure of FIG. 10;

FIG. 12 is an enlarged view of a portion of another semiconductor structure that may be formed by providing conductive material within the via recesses of the semiconductor structure of FIG. 11 to form additional portions of through wafer interconnects therein;

FIG. 13 is an enlarged view of a portion of another semiconductor structure that may be formed by removing the carrier substrate from the semiconductor structure of FIG. 12 and providing conductive bumps over exposed ends of the through wafer interconnects therein;

FIGS. 14 through 16 illustrate additional methods that may be used to process a semiconductor like that shown in FIG. 10 to a semiconductor structure like that shown in FIG. 11; and

FIGS. 17 through 20 illustrate yet further methods that may be used to process a semiconductor like that shown in FIG. 10 to a semiconductor structure like that shown in FIG. 11.

### DETAILED DESCRIPTION

The following description provides specific details, such as material types and processing conditions, in order to provide a thorough description of embodiments of the present disclosure and implementation thereof. However, a person of ordinary skill in the art will understand that the embodiments of the present disclosure may be practiced without employing these specific details and in conjunction with conventional fabrication techniques. In addition, the description provided herein does not form a complete process flow for manufacturing a semiconductor device or system. Only those process acts and structures necessary to understand the embodiments of the present invention are described in detail herein. The materials described herein may be formed (e.g., deposited or grown) by any suitable technique including, but not limited to, spin-coating, blanket coating, Bridgeman and Czochralski processes, chemical vapor deposition (“CVD”), plasma enhanced chemical vapor deposition (“PECVD”), atomic layer deposition (“ALD”), plasma enhanced atomic layer deposition (PEALD), or physical vapor deposition (“PVD”). While the materials described and illustrated herein may be formed as layers, the materials are not limited to layers and may be formed in other three-dimensional configurations.

The terms “horizontal” and “vertical,” as used herein, define relative positions of elements or structures with respect to a major plane or surface of a semiconductor structure (e.g., wafer, die, substrate, etc.), regardless of the orientation of the semiconductor structure, and are orthogonal dimensions interpreted with respect to the orientation of the structure being described. As used herein, the term “vertical” means and includes a dimension substantially perpendicular to the major surface of a semiconductor structure, and the term “horizontal” means a dimension substantially parallel to the major surface of the semiconductor structure.

As used herein, the term “semiconductor structure” means and includes any structure that is used in the formation of a semiconductor device. Semiconductor structures include, for example, dies and wafers (e.g., carrier substrates and device substrates), as well as assemblies or composite structures that include two or more dies and/or wafers three-dimensionally integrated with one another. Semiconductor structures also include fully fabricated semiconductor devices, as well as intermediate structures formed during fabrication of semiconductor devices. Semiconductor structures may comprise conductive, semiconductive materials, and/or non-conductive materials.

As used herein, the term “processed semiconductor structure” means and includes any semiconductor structure that includes one or more at least partially formed device structures. Processed semiconductor structures are a subset of semiconductor structures, and all processed semiconductor structures are semiconductor structures.

As used herein, the term “bonded semiconductor structure” means and includes any structure that includes two or more semiconductor structures that are attached together. Bonded semiconductor structures are a subset of semiconductor structures, and all bonded semiconductor structures are semiconductor structures. Furthermore, bonded semiconductor structures that include one or more processed semiconductor structures are also processed semiconductor structures.

As used herein, the term “device structure” means and includes any portion of a processed semiconductor structure that is, includes, or defines at least a portion of an active or passive component of a semiconductor device to be formed on or in the semiconductor structure. For example, device structures include active and passive components of integrated circuits such as, for example, transistors, transducers, capacitors, resistors, conductive lines, conductive vias, and conductive contact pads.

As used herein, the term “through wafer interconnect” or “TWI” means and includes any conductive via extending through at least a portion of a first semiconductor structure that is used to provide a structural and/or an electrical interconnection between the first semiconductor structure and a second semiconductor structure across an interface between the first semiconductor structure and the second semiconductor structure. Through wafer interconnects are also referred to in the art by other terms such as “through silicon vias” or “through substrate vias” (TSVs) and “through wafer vias” or “TWVs.” TWIs typically extend through a semiconductor structure in a direction generally perpendicular to the generally flat, major surfaces of the semiconductor structure (i.e., in a direction parallel to the “Z” axis).”

As used herein, the term “active surface,” when used in relation to a processed semiconductor structure, means and includes an exposed major surface of the processed semiconductor structure that has been, or will be, processed to form one or more device structures in and/or on the exposed major surface of the processed semiconductor structure.

As used herein, the term “back surface,” when used in relation to a processed semiconductor structure, means and includes an exposed major surface of the processed semiconductor structure on an opposing side of the processed semiconductor structure from an active surface of the semiconductor structure.

As used herein, the term “III-V type semiconductor material” means and includes any material predominantly comprised of one or more elements from group IIIA of the periodic table (B, Al, Ga, In, and Ti) and one or more elements from group VA of the periodic table (N, P, As, Sb, and Bi).

As used herein, the term “coefficient of thermal expansion,” when used with respect to a material or structure, means the average linear coefficient of thermal expansion of the material or structure at room temperature.

As discussed in further detail below, in some embodiments, the present invention includes methods of forming semiconductor structures that include one or more through wafer interconnects therein. The through wafer interconnects may include two or more portions formed in separate processes.

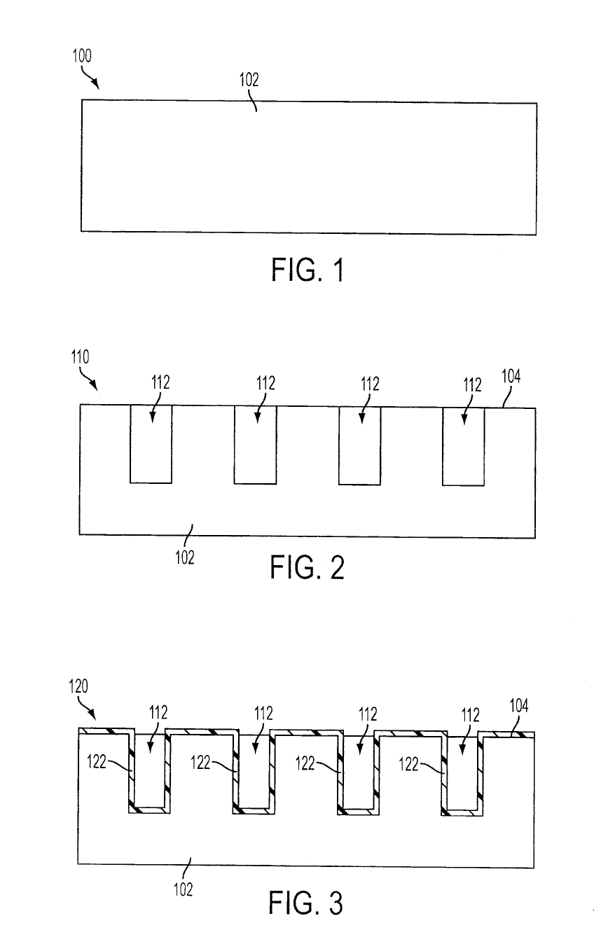

FIG. 1 is a simplified cross-sectional side view of a portion of a first semiconductor structure 100. The first semiconductor structure 100 may comprise a layer or substrate of material 102. For example, the material 102 may comprise a ceramic such as an oxide (e.g., silicon dioxide (SiO₂) or aluminum oxide (Al₂O₃)) or a nitride (e.g., silicon nitride (Si₃N₄) or boron nitride (BN)). As another example, the first semiconductor material 100 may comprise a semiconductor material such as silicon (Si), germanium (Ge), a III-V semiconductor material, etc. Furthermore, the material 102 may comprise a single crystal of semiconductor material or an epitaxial layer of semiconductor material. As one non-limiting example, the material 102 of the first semiconductor structure 100 may comprise a single crystal of bulk silicon material.

FIG. 2 illustrates another semiconductor structure 110 that may be formed by providing via recesses 112 in the semiconductor structure 100 of FIG. 1. The via recesses 112 may be used to form portions of through wafer interconnects, as discussed in further detail below. As shown in FIG. 2, the via recesses 112 may extend into and at least partially through the material 102 of the semiconductor structure 110 from a first major surface 104 thereof. In some embodiments, the via recesses 112 may comprise blind via recesses that extend only partially through the material 102 of the semiconductor structure 110.

The via recesses 112 may have a generally cylindrical cross-sectional shape, or any other cross-sectional shape. The via recesses 112 may have an average cross-sectional dimension (e.g., an average diameter) of about one micrometer (1 μm) or less, or about ten micrometers (10 μm) or less, or even fifty micrometers (50 μm) or less. Furthermore, the via recesses 112 may have an average aspect ratio (i.e., the ratio of the average height to the average cross-sectional dimension) in a range extending from about 0.5 to about 10.0.

FIG. 3 illustrates another semiconductor structure 120 that may be formed by providing a dielectric material 122 at the surfaces of the material 102 within the via recesses 112. By way of example and not limitation, the dielectric material 122 may comprise a ceramic such as an oxide (e.g., silicon dioxide (SiO₂) or aluminum oxide (Al₂O₃)), a nitride (e.g., silicon nitride (Si₃N₄) or boron nitride (BN)), or an oxynitride (e.g., silicon oxynitride). The dielectric material 122 may be formed in situ on or in the exposed surfaces of the material 102 within the via recesses 112. In additional embodiments, the dielectric material 122 may be deposited over the exposed surfaces of the material 102 within the via recesses 112. As one particular non-limiting example, the material 102 may comprise bulk silicon material, the dielectric material 122 may comprise silicon oxide, and the dielectric material 122 may be formed by oxidizing the exposed surfaces of the material 102 within the via recesses 112. In some embodiments, the dielectric material 122 also may be deposited over the first major surface 104 of the semiconductor structure 110 (FIG. 2), as shown in FIG. 3.

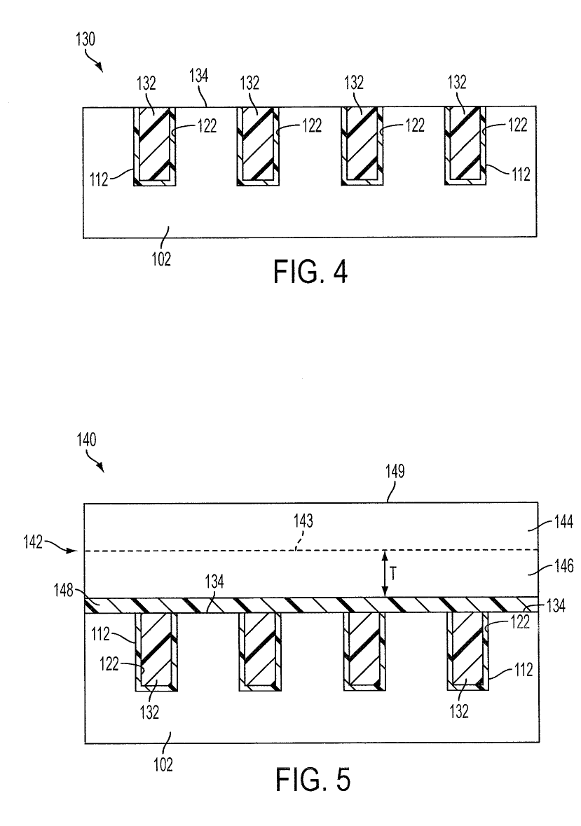

Referring to FIG. 4, the via recesses 112 (FIG. 3) may be filled with a sacrificial material 132. The sacrificial material 132 comprises a material that will ultimately be removed and replaced with another material, as discussed below. The sacrificial material 132 may comprise, for example, polycrystalline silicon material. In other words, the sacrificial material 132 may comprise silicon having a microstructure that includes a plurality of inter-bonded grains of silicon randomly orientated within the microstructure. Such silicon material is commonly referred to in the art as “polysilicon” material. In additional embodiments, the sacrificial material 132 may comprise any other material that may be selectively etched relative to the material 102 (and the optional dielectric material 122) such as a ceramic, a semiconductor material (e.g., polycrystalline SiGe), a polymer material, a metal, etc. In some embodiments, the sacrificial material 132 may comprise one or more additional dielectric materials, such as an oxide, nitride or oxynitride (e.g., silicon dioxide). The sacrificial material 132 may have a composition that is selected such that the atoms of the sacrificial material 132 will not diffuse in any significant manner into surrounding regions of a semiconductor structure upon processing of the semiconductor structure at temperatures greater than about 400° C. to which the semiconductor structure may be subjected during fabrication of transistors or other device structures, as described in further detail below, or that will not detrimentally affect the semiconductor structure should the atoms diffuse in any significant quantity into the surrounding structure during such processes at elevated temperatures. In some embodiments, the sacrificial material 132 may exhibit a coefficient of thermal expansion that is within about forty percent (40%) of a coefficient of thermal expansion exhibited by the material 102, within about twenty percent (20%) of a coefficient of thermal expansion exhibited by the material 102, or even within about five percent (5%) of a coefficient of thermal expansion exhibited by the material 102. Furthermore, in some embodiments, the sacrificial material 132 may comprise a material having a coefficient of thermal expansion that is about 5.0×10⁻⁶° C.⁻¹ or less, about 3.0×10⁻⁶° C.⁻¹ or less, or even about 1.0×10⁻⁶° C.⁻¹ or less.

After providing the sacrificial material 132 within the via recesses 112 (FIG. 3), the surface 134 of the semiconductor structure 130 may be planarized to cause the exposed surfaces of the sacrificial material 132 to be at least substantially coplanar and coextensive with the exposed surface of the material 102 at the surface 134 of the semiconductor structure 130. In more detail, the sacrificial material 132 may be formed conformally over the first major surface 104 (and the optional dielectric material 122), for example, utilizing CVD methods. The sacrificial material 132 may formed to a thickness such that the via recesses 112 are at least substantially entirely filled with the sacrificial material 132. Any excess sacrificial material 132 (and optional dielectric material 132) may then be removed to planarize the surface 134 of the semiconductor structure 130. For example, the surface 134 of the semiconductor structure 130 may be planarized using a chemical process (e.g., a wet or dry chemical etching process), a mechanical process (e.g., a grinding or lapping process), or by a chemical-mechanical polishing (CMP) process.

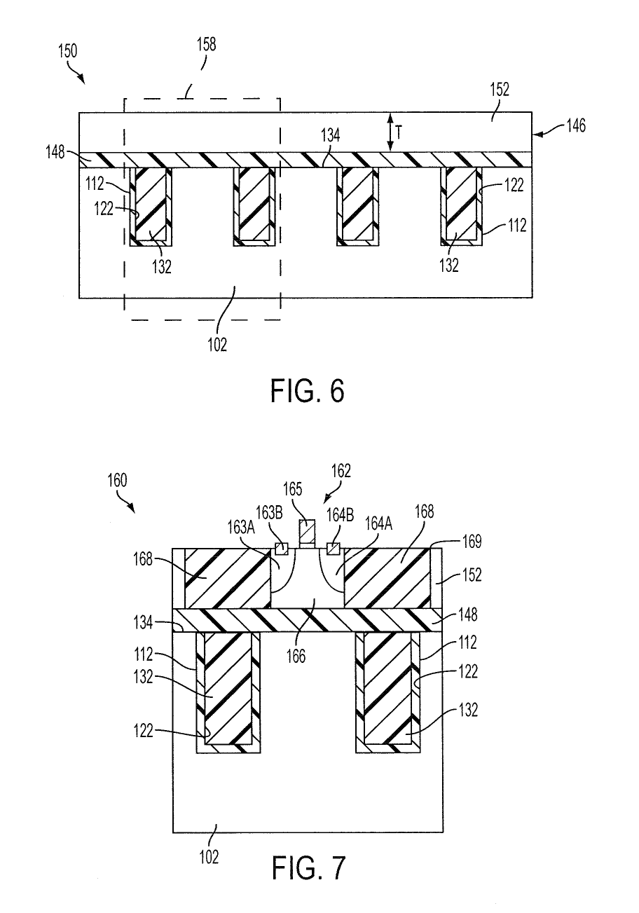

After providing the sacrificial material 132 within the via recesses 112 (FIG. 3) as described above, a thin layer of semiconductor material may be provided over the surface 134 of the semiconductor structure 130. As a non-limiting example, a thin layer of semiconductor material may be provided over the surface 134 of the semiconductor structure 130 as described below with reference to FIGS. 5 and 6.

FIG. 5 illustrates a bonded semiconductor structure that may be formed by bonding another semiconductor structure comprising a substrate 142 to the surface 134 of the semiconductor structure 130 of FIG. 4. The substrate 142 may comprise a semiconductor material such as, for example, silicon (Si), germanium (Ge), a III-V semiconductor material, etc. Furthermore, the material of the substrate 142 may comprise a single crystal of semiconductor material or an epitaxial layer of semiconductor material. As one non-limiting example, the material of the substrate 142 may comprise a single crystal of bulk silicon material.

The substrate 142 may be bonded to the surface 134 using a direct bonding process in which the substrate 142 is directly bonded to the semiconductor structure 130 (FIG. 4) by providing direct atomic or molecular bonds between a bonding surface of the semiconductor structure 130 and a bonding surface of the substrate 142 along a bonding interface therebetween. In other words, the substrate 142 may be directly bonded to the semiconductor structure 130 without using an adhesive or any other intermediate bonding material between the substrate 142 and the semiconductor structure 130. The nature of the atomic or molecular bonds between the substrate 142 and the semiconductor structure 130 will depend upon the material compositions of each of the substrate 142 and the semiconductor structure 130. Thus, in accordance with some embodiments, direct atomic or molecular bonds may be provided between, for example, at least one of silicon oxide and germanium oxide, and at least one of silicon, germanium, silicon oxide, and germanium oxide.

By way of example and not limitation, the bonding surface of the substrate 142 may comprise an oxide material (e.g., silicon dioxide (SiO₂)), and the bonding surface of the semiconductor structure 130 may be at least substantially comprised of the same oxide material (e.g., silicon dioxide (SiO₂)). In such embodiments, a silicon oxide-to-silicon oxide surface direct-bonding process may be used to bond the bonding surface of the substrate 142 to a bonding surface of the semiconductor structure 130. In such embodiments, as shown in FIG. 5, a bonding material 148 (e.g., a layer of oxide such as silicon dioxide) may be disposed between the substrate 142 and the semiconductor structure 130 (FIG. 4) at a bonding interface therebetween. The bonding material 148 may have an average thickness of, for example, about 1,000 angstroms.

In additional embodiments, the bonding surface of the substrate 142 may comprise a semiconductor material (e.g., silicon), and the bonding surface of the semiconductor structure 130 may be at least substantially comprised of the same semiconductor material (e.g., silicon). In such embodiments, a silicon-to-silicon surface direct-bonding process may be used to bond the bonding surface of the substrate 142 to a bonding surface of the semiconductor structure 130.

In some embodiments, the direct bond between the bonding surface of the substrate 142 and the bonding surface of the semiconductor structure 130 may be established by forming each of the bonding surface of the substrate 142 and the bonding surface of the semiconductor structure 130 to have relatively smooth surfaces, and subsequently abutting the bonding surfaces together and maintaining contact between the bonding surfaces during an annealing process.

For example, each of the bonding surface of the substrate 142 and the bonding surface of the semiconductor structure 130 may be formed to have a root mean square surface roughness (R_{RMS}) of about two nanometers (2.0 nm) or less, about one nanometer (1.0 nm) or less, or even about one-quarter of a nanometer (0.25 nm) or less. In some embodiments, each of the bonding surface of the substrate 142 and the bonding surface of the semiconductor structure 130 may be formed to have a root mean square surface roughness (R_{RMS}) of between about one-quarter of a nanometer (0.25 nm) and about two nanometers (2.0 nm), or even between about one-half of a nanometer (0.5 nm) and about one nanometer (1.0 nm).

The annealing process may comprise heating the substrate 142 and the semiconductor structure 130 in a furnace at a temperature of between about one hundred degrees Celsius (100° C.) and about four hundred degrees Celsius (400° C.) for a time of between about two minutes (2 mins.) and about fifteen hours (15 hrs.).

Each of the bonding surface of the substrate 142 and the bonding surface of the semiconductor structure 130 may be formed to be relatively smooth, as mentioned above, using at least one of a mechanical polishing process and a chemical etching process. For example, a chemical-mechanical polishing (CMP) process may be used to planarize and/or reduce the surface roughness of each of the bonding surface of the substrate 142 and the bonding surface of the semiconductor structure 130.

A first portion 144 of the substrate 142 may be removed from the semiconductor structure 140 of FIG. 5, leaving a second portion 146 of the substrate 142 behind over the surface 134 and forming the bonded semiconductor structure 150 of FIG. 6. Put another way, the first portion 144 of the substrate 142 may be separated from the second portion 146 of the substrate 142. The semiconductor structure 150 of FIG. 6 includes a thin layer of semiconductor material 152 over the surface 134. The thin layer of semiconductor material 152 is provided by the second portion 144 of the substrate 142 (FIG. 5).

Referring again to FIG. 5, by way of example and not limitation, the process known in the industry as the SMART-CUT® process may be used to separate the first portion 144 of the substrate 142 from the second portion 146 of the substrate 142. Such processes are described in detail in, for example, U.S. Pat. No. RE 39,484 to Bruel (issued Feb. 6, 2007), U.S. Pat. No. 6,303,468 to Aspar et al. (issued Oct. 16, 2001), U.S. Pat. No. 6,335,258 to Aspar et al. (issued Jan. 1, 2002), U.S. Pat. No. 6,756,286 to Moriceau et al. (issued Jun. 29, 2004), U.S. Pat. No. 6,809,044 to Aspar et al. (issued Oct. 26, 2004), and U.S. Pat. No. 6,946,365 to Aspar et al. (Sep. 20, 2005), the disclosure of each of which patent is hereby incorporated herein in its entirety by this reference.

A plurality of ions (e.g., hydrogen, helium, or inert gas ions) may be implanted into the substrate 142. The ions may be implanted into the substrate 142 before or after attaching the substrate 142 to the semiconductor 130 of FIG. 4, as described above. For example, ions may be implanted into the substrate 142 from an ion source (not shown) positioned on a side of the substrate 142. Ions may be implanted into the substrate 142 along a direction substantially perpendicular to the major surfaces of the substrate 142. As known in the art, the depth at which the ions are implanted into the substrate is at least partially a function of the energy with which the ions are implanted into the substrate. Generally, ions implanted with less energy will be implanted at relatively shallower depths, while ions implanted with higher energy will be implanted at relatively deeper depths.

Ions may be implanted into the substrate 142 with a predetermined energy selected to implant the ions at a desirable depth within the substrate 142. As one particular non-limiting example, the ions may be disposed within the substrate 142 at a selected depth such that the average thickness T of the second portion 146 of the substrate 142 is about three hundred nanometers (300 nm) or less, or even about one hundred nanometers (100 nm) or less. As known in the art, inevitably at least some ions may be implanted at depths other than the desired implantation depth, and a graph of the concentration of the ions as a function of depth into the substrate 142 from a surface of the substrate 142 may exhibit a generally bell-shaped (symmetric or asymmetric) curve having a maximum at a desirable implantation depth.

Upon implantation into the substrate 142, the ions may define a fracture plane 143 (illustrated as a dashed line in FIG. 5) within the substrate 142. The fracture plane 143 may comprise a layer or region within the substrate 142 that is aligned with (e.g., centered about) the plane of maximum ion concentration with the substrate 142. The fracture plane 143 may define a zone of weakness within the substrate 142 along which the substrate 142 may be cleaved or fractured in a subsequent process. The substrate 142 may be cleaved or fractured along the fracture plane 143 by heating the substrate 142, applying a mechanical force to the substrate 142, or by otherwise applying energy to the substrate 142.

In additional embodiments, the second portion 146 of the substrate 142 may be provided over the surface 134 of the semiconductor structure 130 of FIG. 4 by bonding a relatively thick layer of material (e.g., a layer having an average thickness of greater than about 300 microns) such as the substrate 142, and subsequently thinning the relatively thick substrate 142 from the side 149 thereof opposite the surface 134. For example, the substrate 142 may be thinned using a chemical process (e.g., a wet or dry chemical etching process), a mechanical process (e.g., a grinding or lapping process), or by a chemical-mechanical polishing (CMP) process.

In yet further embodiments, a relatively thin layer of semiconductor material (which may be at least substantially similar in composition and configuration to the second portion 146 of the substrate 142) may be formed in situ over (e.g., on) the surface 134 of the semiconductor structure 130 of FIG. 4. For example, a relatively thin layer of silicon material may be formed by depositing material, such as silicon, over the surface 134 of the semiconductor structure 130 of FIG. 4 to a desirable thickness.

After providing a thin layer of semiconductor material 152 over the surface 134 of the semiconductor structure 130 of FIG. 3, one or more device structures may be formed on and/or in the thin layer of semiconductor material 152. In other words, one or more device structures may be formed using the thin layer of semiconductor material 152. By way of example and not limitation, a plurality of transistors may be fabricated using the thin layer of semiconductor material 152.

FIG. 7 illustrates a portion of the bonded semiconductor device 150 of FIG. 6 enclosed within the dashed line 158, subsequent to processing the semiconductor structure 150 to form the bonded and processed semiconductor structure 160 of FIG. 7. The semiconductor structure 160 includes one or more transistors 162. Only one transistor 162 is shown in FIG. 7 for clarity. As shown in FIG. 7, each transistor 162 may include a source that includes a source region 163A and a source contact 163B, a drain that includes a drain region 164A and a drain contact 164B, and a gate structure 165. Each of the source region 163A and the drain region 164A may include regions of the thin layer of semiconductor material 152 that have been doped with one or more dopants to render these regions electrically conductive. The source region 163A and the drain region 164A may be separated from one another by a channel region 166, which may comprise an undoped region of the thin layer of semiconductor material 152. The gate structure 165 may be disposed over the channel region 166 laterally between the source and the drain of the transistor 162. Each of the source contact 163B, the drain contact 164B, and the gate structure 165 may include a conductive material such as one or more metals, or a doped polysilicon material. The conductive material of the gate structure 165 may be electrically isolated from the thin layer of semiconductor material 152 by one or more dielectric materials (e.g., an oxide, a nitride, an oxynitride, etc.)

As shown in FIG. 7, one or more shallow trench isolation structures 168 may be formed in and through the thin layer of semiconductor material 152 proximate the transistors 162. The shallow trench isolation structures 168 may comprise a dielectric material, and may be used to electrically isolate each transistor 162 from other transistors or other device structures of the semiconductor structure 160. By way of example and not limitation, the shallow trench isolation structures 168 may comprise a dielectric material such as an oxide, a nitride, an oxynitride, etc. The shallow trench isolation structures 168 may be vertically aligned (i.e., aligned along a direction perpendicular to the major surfaces of the semiconductor structure 160, such as the surface 134) with the via recesses 112 and the sacrificial material 132 contained therein. In other words, the via recesses 112 and the sacrificial material 132 may be positioned relative to one another such that a straight line may be drawn at least substantially perpendicular to the major surfaces of the semiconductor structure 160, such as the surface 134, that passes through a shallow trench isolation structure 168 and a volume of sacrificial material 132 within one of the via recesses 112.

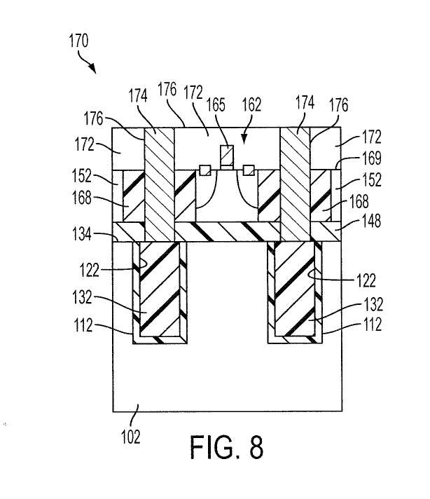

Referring to FIG. 8, a bonded, processed semiconductor structure 170 may be formed by providing a layer of dielectric material 172 (e.g., an interlayer dielectric material) over an exposed surface 169 of the semiconductor structure 160 of FIG. 7 in and/or on which the one or more transistors 162 and shallow trench isolation structures 168 have been formed, and forming first portions 174 of through wafer interconnects therein.

The layer of dielectric material 172 may be formed on or deposited over the surface 169, and may have an average thickness large enough to cover the gate structure 165 of the transistor 162, as shown in FIG. 8. The layer of dielectric material 172 may comprise a dielectric material such as an oxide, a nitride, an oxynitride, etc.

With continued reference to FIG. 8, first portions 174 of through wafer interconnects may be formed in the semiconductor structure 170. The first portions 174 of through wafer interconnects may comprise a conductive material such as one or more metals, doped polysilicon, etc. The first portions 174 of through wafer interconnects may be formed by forming via recesses 176 through the layer of dielectric material 172, through the shallow trench isolation structures 168, and through any bonding material 148 to the sacrificial material 132 in the via recesses 112 within the material 102. In some embodiments, the shallow trench isolation structures 168 may not extend entirely through the thin layer of semiconductor material 152, and the via recesses 176 also may extend through at least a portion of the thin layer of semiconductor material 152. The via recesses 176 may be formed, for example, using a masking and etching process. A mask layer may be provided over the exposed major surface 178 of the layer of dielectric material 172. The mask layer may be patterned to form holes or apertures extending through the mask layer at the locations at which it is desired to form the via recesses 176. The apertures in the mask layer may have a cross-sectional size and shape corresponding to a desirable cross-sectional size and shape of the via recesses 176 to be formed. The semiconductor structure 170 then may be exposed to one or more etchants that will etch the various materials through which the via recesses 176 are to extend without etching (at any significant rate) the mask layer. For example, a wet chemical etching process or a dry reactive ion etching process may be used to form the via recesses 176 through the layer of dielectric material 172, the shallow trench isolation structures 168, and any bonding material 148 to the sacrificial material 132.

In some embodiments, the via recesses 176 may have an average aspect ratio (i.e., the ratio of the average height to the average cross-sectional dimension) in a range extending from about 0.5 to about 10.0.

After forming the via recesses 176, conductive material may be provided within the via recesses 176. For example, one or metal materials may be deposited within the via recesses 176 using an electroless plating process and/or an electrolytic plating process.

The first portions 174 of through wafer interconnects, like the shallow trench isolation structures 168 through which they extend, may be vertically aligned (i.e., aligned along a direction perpendicular to the major surfaces of the semiconductor structure 170, such as the surface 134) with the via recesses 112 and the sacrificial material 132 contained therein. In other words, the first portions 174 of through wafer interconnects and the sacrificial material 132 may be positioned relative to one another such that a straight line may be drawn at least substantially perpendicular to the major surfaces of the semiconductor structure 170, such as the surface 134, that passes through a first portion 174 of a through wafer interconnect and a volume of sacrificial material 132 within one of the via recesses 112.

After forming the first portions 174 of through wafer interconnects, additional processing may be carried out to form additional device structures, such as conductive vias, lines, traces, and pads over the exposed major surface 178 of the layer of dielectric material 172. Such processes may include what are referred to in the art as “Back End Of Line” (BEOL) processes.

For example, FIG. 9 illustrates a bonded and processed semiconductor structure 180 that may be formed by fabrication of a plurality of device structures 182 within one or more surrounding dielectric materials 184. The device structures 182 may include one or more of conductive vias, lines, traces, and pads comprising a conductive material such as one or more metals or doped polysilicon. The one or more surrounding dielectric materials 184 may comprise an oxide, a nitride, an oxynitride, etc. The various device structures 182 and the surrounding dielectric material 184 may be formed lithographically (i.e., layer-by-layer) over the major surface 178 of the layer of dielectric material 172 using processes known in the art.

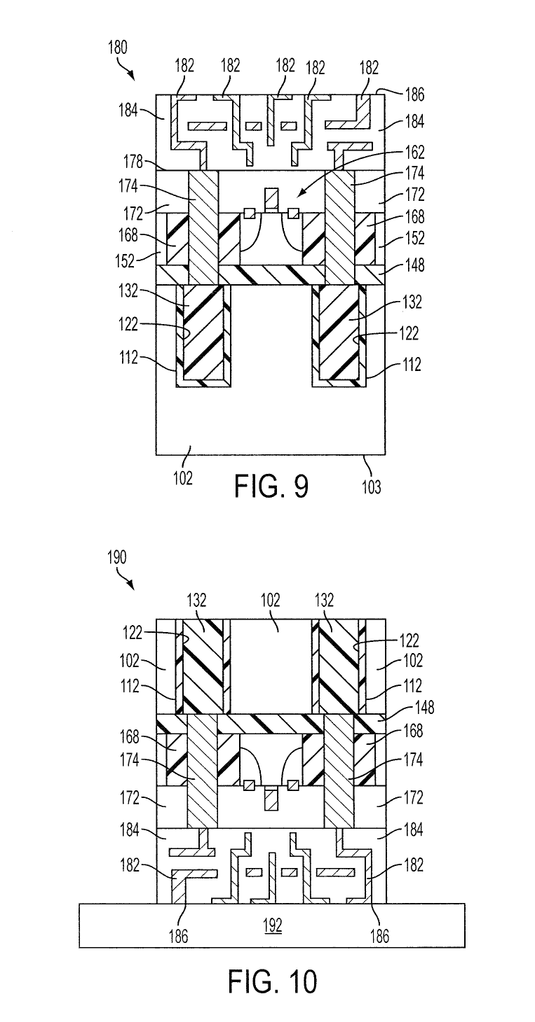

After forming device structures 182 over the layer of dielectric material 172 as discussed above in relation to FIG. 9, a portion of the material 102 may be removed from the semiconductor structure 180 to expose the sacrificial material 132 through the material 102 as shown in the bonded and processed semiconductor structure 190 of FIG. 10. The portion of the material 102 may be removed from the exposed major surface 103 (FIG. 9) of the material 102 on the side of the semiconductor structure 180 opposite the active surface 186. By way of example and not limitation, the portion of the material 102 may be removed using, for example, one or more of a chemical etching process, a mechanical polishing process, or a chemical-mechanical polishing (CMP) process. If a dielectric material 122 is disposed between the sacrificial material 132 and the material 102, as shown in FIG. 9, a portion of the dielectric material 122 also may be removed to expose the sacrificial material 132 to the exterior of the semiconductor structure 190, as shown in FIG. 10.

Optionally, the active surface 186 of the semiconductor structure 180 of FIG. 9 may be bonded to a carrier substrate 192, as shown in FIG. 10, prior to removing the material 102 to expose the sacrificial material 132 to assist in handling of the semiconductor structure while removing the material 102.

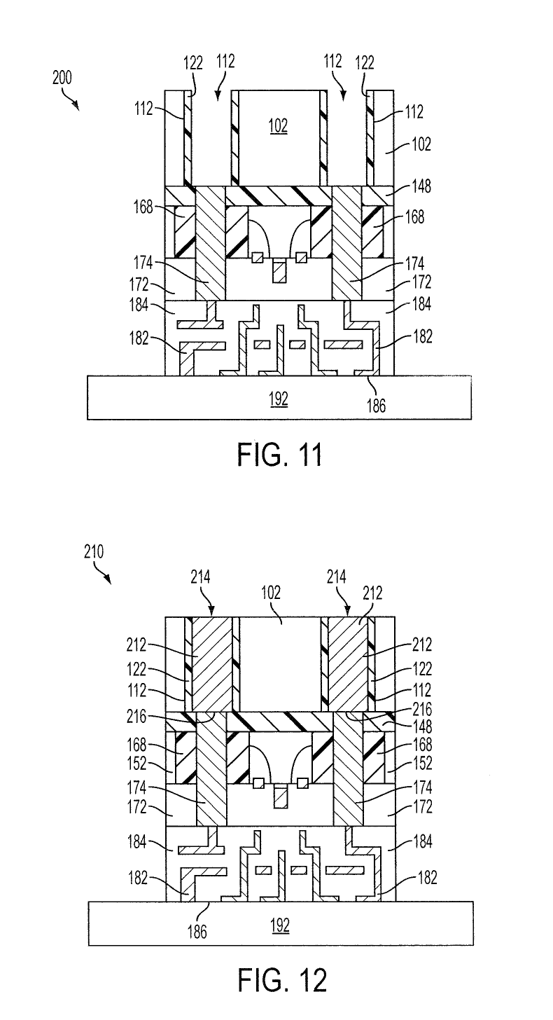

After exposing the sacrificial material 132 to the exterior of the semiconductor structure 190 as shown in FIG. 10, the sacrificial material 132 may be removed from within the via recesses 112 to form the bonded and processed semiconductor structure 200 shown in FIG. 11. By way of example and not limitation, a wet chemical etching process may be used to remove the sacrificial material 132 from within the via recesses 112. An etchant that will etch (e.g., remove) the sacrificial material 132 from the semiconductor structure 200 at a faster rate than a rate at which the etchant will remove the dielectric material 122 and any bonding material 148 may be used to remove the sacrificial material 132. In other words, an etchant that is selective to the sacrificial material 132 (and optionally relative to the optionally dielectric material 122) and any bonding material 148 may be used to remove the sacrificial material 132. In embodiments in which the sacrificial material comprises polysilicon material, the etchant may comprise a mixture of nitric acid, hydrofluoric acid, and water. In embodiments in which the sacrificial material 132 comprises a further dielectric material, such as, for example, silicon dioxide, the sacrificial material 132 may be etched selectively using an etch solution comprising hydrofluoric acid or a plasma etching process (e.g., utilizing a sulfur hexafluoride SF₆ etch chemistry).

As shown in FIG. 12, conductive material may be provided within the via recesses 112 (within the space vacated by removal of the sacrificial material 132) to form second portions 212 of through wafer interconnects 214. The through wafer interconnects 214 include the first portions 174 and the second portions 212. Direct physical and electrical contact may be established between the first portions 174 and the second portions 212 of the through wafer interconnects 214.

The conductive material of the second portions 212 of the through wafer interconnects 214 may comprise a conductive material such as one or more metals, doped polysilicon, etc. In some embodiments, the conductive material of the second portions 212 of the through wafer interconnects 214 may be at least substantially identical to the conductive material of the first portions 174 of the through wafer interconnects 214. The conductive material may be provided within the via recesses 112, 176. For example, one or metal materials may be deposited within the via recesses 176 using an electroless plating process and/or an electrolytic plating process.

The through wafer interconnects 214 include the first portions 174 and the second portions 212 thereof. As a result of forming the first portions 174 and the second portions 212 in separate processes at different sequential times during fabrication of the semiconductor structure 210, there may be a discrete, identifiable boundary 216 in the microstructure between the first portions 174 and the second portions 212 of the through wafer interconnects 214 in some embodiments of the invention. The identifiable boundary 216 may be located proximate a major surface of the thin layer of semiconductor material 152. For example, the identifiable boundary 216 may be coplanar with the bonding material 148 disposed at a major surface of the thin layer of semiconductor material 152. Furthermore, the semiconductor structure 210 may be oriented parallel to the active surface 186, as shown in FIG. 12.

In some embodiments, the through wafer interconnects 214 may have an average aspect ratio (i.e., the ratio of the average height to the average cross-sectional dimension) in a range extending from about 0.5 to about 10.0.

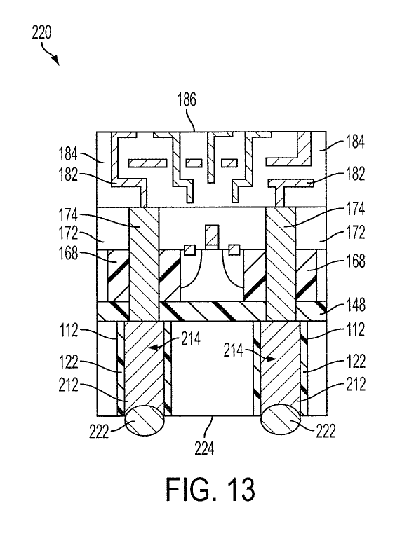

After forming the through wafer interconnects 214 as described above, the carrier substrate 192 may be removed from the bonded and processed semiconductor structure 210 of FIG. 12 to form the bonded and processed semiconductor structure 220 of FIG. 13. As shown in FIG. 13, conductive bumps 222 may be structurally and electrically coupled with the exposed ends of the second portions 212 of the through wafer interconnects 214 at the back surface 224 of the semiconductor structure 220 opposite the active surface 186. The conductive bumps 222 may comprise a conductive material such as, for example, a conductive solder alloy.

The semiconductor structure 220 shown in FIG. 13 optionally may be further processed and packaged, if needed or desirable. The semiconductor structure 220 subsequently may be structurally and electrically coupled to another structure, such as a printed circuit board, another semiconductor structure (e.g., another die or wafer), etc., using the conductive bumps 222. In additional embodiments, the semiconductor structure 220 may be structurally and electrically coupled to another structure using other devices and techniques known in the art such as, for example, using conductive leads, anisotropically conductive film, etc.

Referring again to FIG. 10, in some embodiments of the invention, it may be relatively difficult to selectively etch the sacrificial material 132 within the via recesses 112 without etching other material of the semiconductor structure 190. In such embodiments, it may be desirable to protect other materials of the semiconductor structure 190 prior to etching the sacrificial material 132 as described hereinabove.

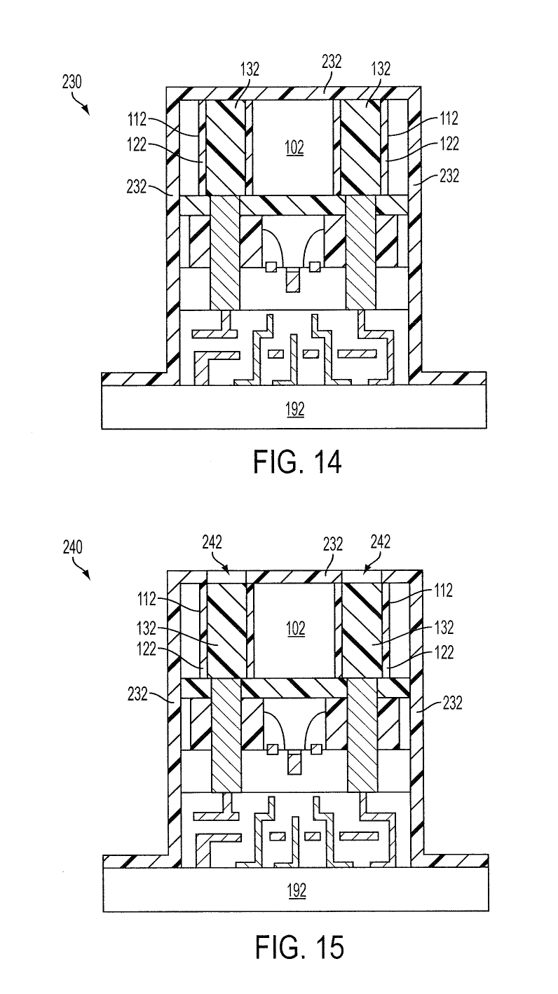

For example, FIG. 14 illustrates a semiconductor structure 230 that may be formed by depositing a mask layer 232 over the surfaces of the semiconductor structure 190 of FIG. 10 in such a manner as to at least substantially cover all exposed surfaces of the semiconductor structure 230, except for possibly some surfaces of the carrier substrate 192. The mask layer 232 may comprise a ceramic material such as an oxide (e.g., silicon dioxide (SiO₂) or aluminum oxide (Al₂O₃)), a nitride (e.g., silicon nitride (Si₃N₄) or boron nitride (BN)), or an oxynitride.

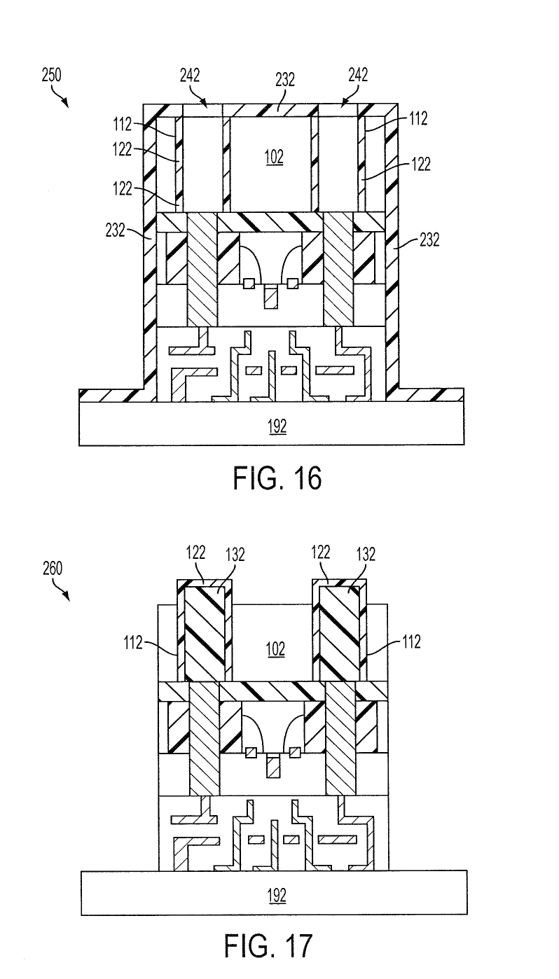

As shown in FIG. 15, the mask layer 232 may be patterned to form openings 242 that extend through the mask layer 232 resulting in the bonded and processed semiconductor structure 240 of FIG. 15. A photolithographic masking and etching process such as those known in the art may be used to form the openings 242 through the mask layer 232. The openings 242 may be sized, shaped, and located to expose the sacrificial material 132 in the via recesses 112 through the openings 242. The semiconductor structure 240 then may be subjected to a wet or dry etching process using an etchant that is selective to the sacrificial material 132 relative to the material of the mask layer 232. Such an etching process will result in removal of the sacrificial material 132 from within the via recesses 112, resulting in the semiconductor structure 250 of FIG. 16. The mask layer 232 then may be removed from the semiconductor structure 250 of FIG. 16 to form a semiconductor structure at least substantially identical to the semiconductor structure 200 of FIG. 11.

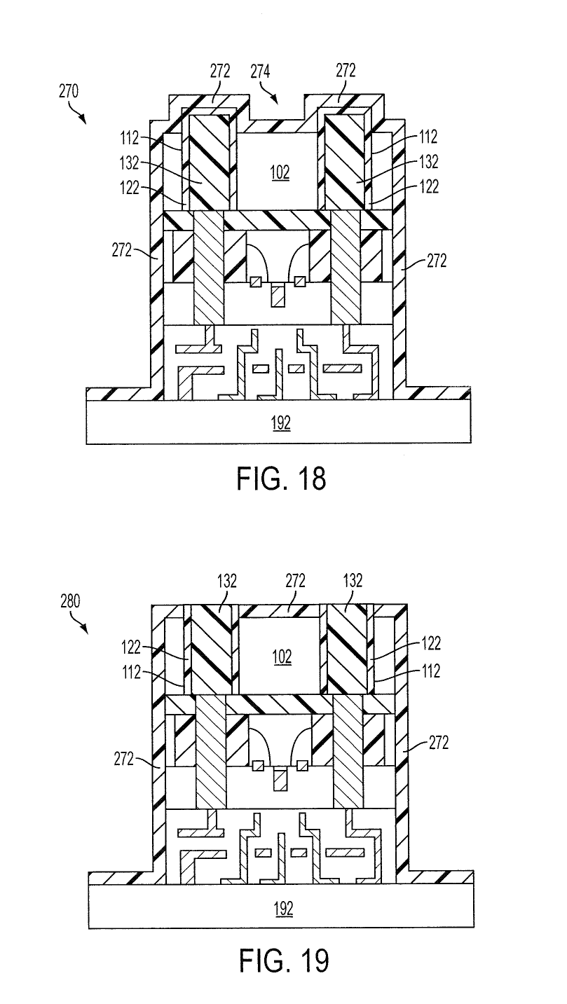

In additional methods, upon thinning the material 102 as previously discussed in relation to FIGS. 9 and 10, the material 102 may be recessed relative to the sacrificial material 132, and/or the optional dielectric material 122, to form the semiconductor structure 260 of FIG. 17. By way of example and not limitation, the material 102 may be recessed relative to the sacrificial material 132, and/or the optional dielectric material 122, by about 2,000 angstroms. After forming the semiconductor structure 260 of FIG. 17, a mask layer 272 may be deposited over the semiconductor structure 260 to form the semiconductor structure 270 of FIG. 18. The mask layer 272 may comprise a ceramic material such as an oxide (e.g., silicon dioxide (SiO₂) or aluminum oxide (Al₂O₃)), a nitride (e.g., silicon nitride (Si₃N₄) or boron nitride (BN)), or an oxynitride. As shown in FIG. 18, the semiconductor structure 270 may include a major surface 274 on a side thereof opposite the carrier substrate 192.

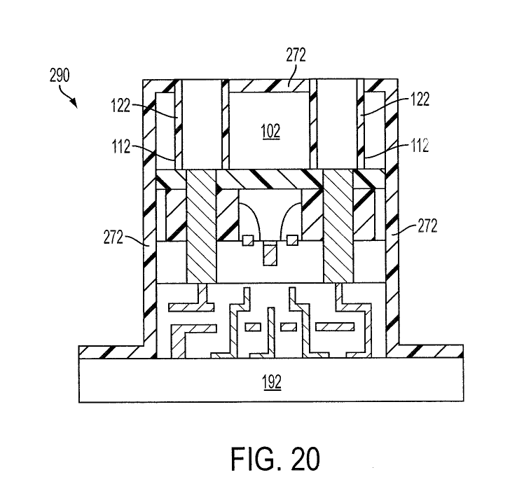

The major surface 274 of the semiconductor structure 270 of FIG. 18 may be subjected to a planarization process, such as a chemical-mechanical polishing (CMP) process, to remove the portions of the mask layer 272 (and portions of any dielectric material 122) over the volumes of sacrificial material 132 within the via recesses 112 to form the bonded and processed semiconductor structure 280 of FIG. 19. As shown in FIG. 19, the sacrificial material 132 may be exposed through the mask layer 272 after planarizing the major surface 274 (FIG. 18). Upon exposing the sacrificial material 132, the semiconductor structure 280 then may be subjected to a wet or dry etching process using an etchant that is selective to the sacrificial material 132 relative to the material of the mask layer 272. Such an etching process will result in removal of the sacrificial material 132 from within the via recesses 112, resulting in the bonded and processed semiconductor structure 290 of FIG. 20. The mask layer 272 then may be removed from the semiconductor structure 290 of FIG. 20 to form a semiconductor structure at least substantially identical to the semiconductor structure 200 of FIG. 11, which then may be further processed as previously described.

Forming through wafer interconnects in a multi-step process (e.g., a two-step process), as described above in relation to the through wafer interconnects 214, may improve the yield of properly operating semiconductor structures during manufacturing because the aspect ratios of the different portions of the through wafer interconnects are smaller relative to the aspect ratios of the entire through wafer interconnects, which may result in easier etching of the via recesses in which the different portions of the through wafer interconnects are formed, improved coverage of insulating dielectric materials over exposed surfaces within the via recesses, and improved plating of conductive material within the via recesses to form the different sections of the through wafer interconnects. Furthermore, fabrication of transistors, such as the transistors 162 described herein, may subject the semiconductor structure to temperatures of greater than about 400° C. If a conductive metal were disposed in via recesses during processing of the semiconductor structure at such elevated temperatures, the metal atoms might diffuse into other regions of the semiconductor structure, which diffusion could detrimentally affect operation of the semiconductor structure. Furthermore, mismatch between the coefficient of thermal expansion of such a metal material and the surrounding dielectric and semiconductor materials could result in structural damage to the semiconductor structure. Thus, by providing a sacrificial material within via recesses in a semiconductor structure prior to fabricating the transistors, and substituting the sacrificial material with another conductive material subsequent to fabricating the transistors may avoid such structural damage or reduce the likelihood that such structural damage might occur.

Additional non-limiting embodiments of the invention are described below:

### Embodiment 1

A method of fabricating a semiconductor structure, comprising: providing a sacrificial material within at least one via recess extending partially through a semiconductor structure; forming a first portion of at least one through wafer interconnect in the semiconductor structure, and aligning the first portion of the at least one through wafer interconnect with the at least one via recess; and replacing the sacrificial material within the at least one via recess with conductive material and forming a second portion of the at least one through wafer interconnect in electrical contact with the first portion of the at least one through wafer interconnect.

### Embodiment 2

The method of Embodiment 1, wherein forming a first portion of at least one through wafer interconnect in the semiconductor structure further comprises extending the first portion of the at least one through wafer interconnect through a dielectric material.

### Embodiment 3

The method of claim 1, wherein providing the sacrificial material within the at least one via recess extending partially through the semiconductor structure comprises: forming at least one blind via recess extending partially through the semiconductor structure from a surface thereof; and providing at least one of polysilicon material, silicon germanium (SiGe), a III-V semiconductor material, and a dielectric material within the at least one blind via recess.

### Embodiment 4

The method of claim 3, wherein providing at least one of polysilicon material, silicon germanium (SiGe), a III-V semiconductor material, and a dielectric material within the at least one blind via recess comprises providing polysilicon material within the at least one blind via recess.

### Embodiment 5

The method of Embodiment 3, further comprising forming the at least one via recess through bulk silicon material.

### Embodiment 6

The method of Embodiment 4, further comprising providing a dielectric material between the bulk silicon material and the polysilicon material within the at least one blind via recess.

### Embodiment 7

The method of Embodiment 3, further comprising providing a thin layer of semiconductor material over a surface of the semiconductor structure after providing the polysilicon material within the at least one blind via recess.

### Embodiment 8

The method of Embodiment 7, wherein providing the thin layer of semiconductor material over the surface of the semiconductor structure comprises: implanting ions into a substrate comprising semiconductor material to form a fracture plane in the substrate; bonding the substrate to the surface of the semiconductor structure; and fracturing the substrate along the fracture plane and separating the thin layer of semiconductor material from a remaining portion of the substrate, the thin layer of semiconductor material remaining bonded to the surface of the semiconductor structure.

### Embodiment 9

The method of Embodiment 8, wherein bonding the substrate to the surface of the semiconductor structure comprises directly bonding the substrate to the surface of the semiconductor structure.

### Embodiment 10

The method of Embodiment 7, further comprising forming at least a portion of a device structure using the thin layer of semiconductor material.

### Embodiment 11

The method of Embodiment 10, wherein forming the at least a portion of the device structure using the thin layer of semiconductor material comprises forming at least a portion of a transistor using the thin layer of semiconductor material.

### Embodiment 12

The method of Embodiment 7, wherein providing the thin layer of semiconductor material over the surface of the semiconductor structure comprises forming the thin layer to have an average thickness of about three hundred nanometers (300 nm) or less.

### Embodiment 13

The method of Embodiment 12, wherein providing the thin layer of semiconductor material over the surface of the semiconductor structure comprises forming the thin layer to have an average thickness of about one hundred nanometers (100 nm) or less.

### Embodiment 14

The method of any one of Embodiments 1 through 13, further comprising thinning the semiconductor structure after forming the first portion of the at least one through wafer interconnect and prior to replacing the sacrificial material with the conductive material and forming the second portion of the at least one through wafer interconnect.

### Embodiment 15

The method of Embodiment 14, wherein thinning the semiconductor structure comprises exposing the sacrificial material to an exterior of the semiconductor structure.

### Embodiment 16

The method of Embodiment 14, further comprising: attaching the semiconductor structure to a carrier substrate prior to thinning the semiconductor structure; and removing the carrier substrate from the semiconductor structure after thinning the semiconductor structure.

### Embodiment 17

A method of fabricating a semiconductor structure, comprising: providing a sacrificial material within at least one via recess extending into a surface of a semiconductor structure; providing a layer of semiconductor material over the surface of the semiconductor structure; fabricating at least one device structure using the layer of semiconductor material; forming a first portion of at least one through wafer interconnect extending through the layer of semiconductor material; thinning the semiconductor structure from a side thereof opposite the layer of semiconductor material; removing the sacrificial material from within the at least one via recess in the semiconductor structure and exposing the first portion of the at least one through wafer interconnect within the via recess; and providing conductive material within the via recess and forming a second portion of the at least one through wafer interconnect.

### Embodiment 18

The method of Embodiment 17, wherein providing the sacrificial material within the at least one via recess comprises providing polysilicon material within the at least one via recess.

### Embodiment 19

The method of Embodiment 17 or Embodiment 18, further comprising providing a dielectric material between the sacrificial material and the semiconductor structure within the at least one via recess.

### Embodiment 20

The method of any one of Embodiments 17 through 19, wherein providing the layer of semiconductor material over the surface of the semiconductor structure comprises transferring the layer of semiconductor material from a substrate to the semiconductor structure.

### Embodiment 21

The method of Embodiment 20, wherein transferring the layer of semiconductor material from a substrate to the semiconductor structure comprises: implanting ions into the substrate; bonding the substrate to the semiconductor structure; and fracturing the substrate along a plane defined by the implanted ions within the substrate and separating the layer of semiconductor material from a remaining portion of the substrate.

### Embodiment 22

The method of any one of Embodiments 17 through 21, wherein providing the layer of semiconductor material over the surface of the semiconductor structure comprises selecting the layer of semiconductor material to have an average thickness of about one hundred nanometers (100 nm) or less.

### Embodiment 23

The method of any one of Embodiments 17 through 222, further comprising: attaching the semiconductor structure to a carrier substrate prior to thinning the semiconductor structure; and removing the carrier substrate from the semiconductor structure after thinning the semiconductor structure.

### Embodiment 24

The method of any one of Embodiments 17 through 23, further comprising forming a conductive bump on the at least one through wafer interconnect.

### Embodiment 25

A semiconductor structure, comprising: a sacrificial material within at least one via recess extending partially through a semiconductor structure from a surface of the semiconductor structure; a semiconductor material disposed over the surface of the semiconductor structure; at least one device structure comprising at least a portion of the semiconductor material disposed over the surface of the semiconductor structure; a first portion of at least one through wafer interconnect extending through the semiconductor material disposed over the surface of the semiconductor structure, the first portion of the at least one through wafer interconnect aligned with the at least one via recess.

### Embodiment 26

The semiconductor structure of Embodiment 25, further comprising a volume of dielectric material at least partially surrounded by the semiconductor material disposed over the surface of the semiconductor structure, the first portion of the at least one through wafer interconnect extending through and directly contacting the volume of dielectric material.

### Embodiment 27

The semiconductor structure of Embodiment 26, wherein the volume of dielectric material comprises a shallow trench isolation structure.

### Embodiment 28

The semiconductor structure of any one of Embodiments 25 through 27, wherein the sacrificial material comprises polysilicon material.

### Embodiment 29

The semiconductor structure of any one of Embodiments 25 through 28, wherein the at least one device structure comprises at least one transistor.

### Embodiment 30

The semiconductor structure of any one of Embodiments 25 through 29, wherein the sacrificial material is exposed to an exterior of the semiconductor structure on a side thereof opposite the semiconductor material disposed over the surface of the semiconductor structure.

### Embodiment 31

The semiconductor structure of any one of Embodiments 25 through 30, further comprising a carrier substrate attached to the semiconductor structure.

### Embodiment 32

The semiconductor structure of any one of Embodiments 25 through 31, wherein the semiconductor material disposed over the surface of the semiconductor structure comprises a layer of the semiconductor material having an average thickness of about three hundred nanometers (300 nm) or less.

### Embodiment 33

The semiconductor structure of Embodiment 32, wherein the layer of the semiconductor material has an average thickness of about one hundred nanometers (100 nm) or less.

### Embodiment 34

A semiconductor structure, comprising: an active surface; a back surface; at least one transistor located within the semiconductor structure between the active surface and the back surface; at least one through wafer interconnect extending at least partially through the semiconductor structure from at least one of the active surface and the back surface, the at least one through wafer interconnect comprising: a first portion; a second portion; and an identifiable boundary between a microstructure of the first portion and a microstructure of the second portion.

### Embodiment 35

The semiconductor structure of Embodiment 34, wherein the at least one transistor comprises at least a portion of a thin layer of semiconductor material.

### Embodiment 36

The semiconductor structure of Embodiment 35, wherein the thin layer of semiconductor material has an average thickness of about one hundred nanometers (100 nm) or less.

### Embodiment 37

The semiconductor structure of Embodiment 35 or Embodiment 36, wherein the identifiable boundary is located proximate a major surface of the thin layer of semiconductor material.

### Embodiment 38

The semiconductor structure of any one of Embodiments 34 through 37, wherein the identifiable boundary is oriented parallel to at least one of the active surface and the back surface.

While embodiments of the present invention have been described herein using certain examples, those of ordinary skill in the art will recognize and appreciate that the invention is not limited to the particulars of the example embodiments. Rather, many additions, deletions and modifications to the example embodiments may be made without departing from the scope of the invention as hereinafter claimed. For example, features from one embodiment may be combined with features of other embodiments while still being encompassed within the scope of the invention as contemplated by the inventors.

What is claimed is:

1. A method of fabricating a semiconductor structure, comprising:
providing a sacrificial material within at least one via recess extending partially through a semiconductor structure;
forming a first portion of at least one through wafer interconnect in the semiconductor structure, and aligning the first portion of the at least one through wafer interconnect with the at least one via recess; and
replacing the sacrificial material within the at least one via recess with conductive material and forming a second portion of the at least one through wafer interconnect in electrical contact with the first portion of the at least one through wafer interconnect.

2. The method of claim 1, wherein forming a first portion of at least one through wafer interconnect in the semiconductor structure further comprises extending the first portion of the at least one through wafer interconnect through a dielectric material.

3. The method of claim 1, wherein providing the sacrificial material within the at least one via recess extending partially through the semiconductor structure comprises:
forming at least one blind via recess extending partially through the semiconductor structure from a surface thereof; and
providing at least one of polysilicon material, silicon germanium (SiGe), a III-V semiconductor material, and a dielectric material within the at least one blind via recess.

4. The method of claim 3, wherein providing at least one of polysilicon material, silicon germanium (SiGe), a III-V semiconductor material, and a dielectric material within the at least one blind via recess comprises providing polysilicon material within the at least one blind via recess.

5. The method of claim 3, further comprising forming the at least one via recess through bulk silicon material.

6. The method of claim 5, further comprising providing a dielectric material between the bulk silicon material and the polysilicon material within the at least one blind via recess.

7. The method of claim 3, further comprising providing a thin layer of semiconductor material over a surface of the semiconductor structure after providing the poly silicon material within the at least one blind via recess.

8. The method of claim 7, wherein providing the thin layer of semiconductor material over the surface of the semiconductor structure comprises:
implanting ions into a substrate comprising semiconductor material to form a fracture plane in the substrate;
bonding the substrate to the surface of the semiconductor structure; and
fracturing the substrate along the fracture plane and separating the thin layer of semiconductor material from a remaining portion of the substrate, the thin layer of semiconductor material remaining bonded to the surface of the semiconductor structure.

9. The method of claim 8, wherein bonding the substrate to the surface of the semiconductor structure comprises directly bonding the substrate to the surface of the semiconductor structure.

10. The method of claim 7, further comprising forming at least a portion of a device structure using the thin layer of semiconductor material.

11. The method of claim 10, wherein forming the at least a portion of the device structure using the thin layer of semiconductor material comprises forming at least a portion of a transistor using the thin layer of semiconductor material.

12. The method of claim 7, wherein providing the thin layer of semiconductor material over the surface of the semiconductor structure comprises forming the thin layer to have an average thickness of about three hundred nanometers (300 nm) or less.

13. The method of claim 12, wherein providing the thin layer of semiconductor material over the surface of the semiconductor structure comprises forming the thin layer to have an average thickness of about one hundred nanometers (100 nm) or less.

14. The method of claim 1, further comprising thinning the semiconductor structure after forming the first portion of the at least one through wafer interconnect and prior to replacing the sacrificial material with the conductive material and forming the second portion of the at least one through wafer interconnect.

15. The method of claim 14, wherein thinning the semiconductor structure comprises exposing the sacrificial material to an exterior of the semiconductor structure.

16. The method of claim 14, further comprising:
attaching the semiconductor structure to a carrier substrate prior to thinning the semiconductor structure; and
removing the carrier substrate from the semiconductor structure after thinning the semiconductor structure.

17. A method of fabricating a semiconductor structure, comprising:
providing a sacrificial material within at least one via recess extending into a surface of a semiconductor structure;
providing a layer of semiconductor material over the surface of the semiconductor structure;
fabricating at least one device structure using the layer of semiconductor material;
forming a first portion of at least one through wafer interconnect extending through the layer of semiconductor material;
thinning the semiconductor structure from a side thereof opposite the layer of semiconductor material;
removing the sacrificial material from within the at least one via recess in the semiconductor structure and exposing the first portion of the at least one through wafer interconnect within the via recess; and
providing conductive material within the via recess and forming a second portion of the at least one through wafer interconnect.

18. The method of claim 17, wherein providing the sacrificial material within the at least one via recess comprises providing polysilicon material within the at least one via recess.

19. The method of claim 17, further comprising providing a dielectric material between the sacrificial material and the semiconductor structure within the at least one via recess.

20. The method of claim 17, wherein providing the layer of semiconductor material over the surface of the semiconductor structure comprises transferring the layer of semiconductor material from a substrate to the semiconductor structure.

21. The method of claim 20, wherein transferring the layer of semiconductor material from a substrate to the semiconductor structure comprises:
implanting ions into the substrate;
bonding the substrate to the semiconductor structure; and
fracturing the substrate along a plane defined by the implanted ions within the substrate and separating the layer of semiconductor material from a remaining portion of the substrate.

22. The method of claim 17, wherein providing the layer of semiconductor material over the surface of the semiconductor structure comprises selecting the layer of semiconductor material to have an average thickness of about one hundred nanometers (100 nm) or less.

23. The method of claim 17, further comprising:
attaching the semiconductor structure to a carrier substrate prior to thinning the semiconductor structure; and
removing the carrier substrate from the semiconductor structure after thinning the semiconductor structure.

24. The method of claim 17, further comprising forming a conductive bump on the at least one through wafer interconnect.

25. A semiconductor structure, comprising:
a sacrificial material within at least one via recess extending partially through a semiconductor structure from a surface of the semiconductor structure;
a semiconductor material disposed over the surface of the semiconductor structure;
at least one device structure comprising at least a portion of the semiconductor material disposed over the surface of the semiconductor structure;
a first portion of at least one through wafer interconnect extending through the semiconductor material disposed over the surface of the semiconductor structure, the first portion of the at least one through wafer interconnect aligned with the at least one via recess.

26. The semiconductor structure of claim 25, further comprising a volume of dielectric material at least partially surrounded by the semiconductor material disposed over the surface of the semiconductor structure, the first portion of the at least one through wafer interconnect extending through and directly contacting the volume of dielectric material.

27. The semiconductor structure of claim 26, wherein the volume of dielectric material comprises a shallow trench isolation structure.

28. The semiconductor structure of claim 25, wherein the sacrificial material comprises polysilicon material.

29. The semiconductor structure of claim 25, wherein the at least one device structure comprises at least one transistor.

30. The semiconductor structure of claim 25, wherein the sacrificial material is exposed to an exterior of the semiconductor structure on a side thereof opposite the semiconductor material disposed over the surface of the semiconductor structure.

31. The semiconductor structure of claim 30, further comprising a carrier substrate attached to the semiconductor structure.

32. The semiconductor structure of claim 25, wherein the semiconductor material disposed over the surface of the semiconductor structure comprises a layer of the semiconductor material having an average thickness of about three hundred nanometers (300 nm) or less.

33. The semiconductor structure of claim 32, wherein the layer of the semiconductor material has an average thickness of about one hundred nanometers (100 nm) or less.

34. A semiconductor structure, comprising:
an active surface;
a back surface;
at least one transistor located within the semiconductor structure between the active surface and the back surface;
at least one through wafer interconnect extending at least partially through the semiconductor structure from at least one of the active surface and the back surface, the at least one through wafer interconnect comprising:
a first portion;
a second portion; and
an identifiable boundary between a microstructure of the first portion and a microstructure of the second portion.

35. The semiconductor structure of claim 34, wherein the at least one transistor comprises at least a portion of a thin layer of semiconductor material.

36. The semiconductor structure of claim 35, wherein the at least a portion of the thin layer of semiconductor material has an average thickness of about one hundred nanometers (100 nm) or less.

37. The semiconductor structure of claim 35, wherein the identifiable boundary is located proximate a major surface of the at least a portion of the thin layer of semiconductor material.

38. The semiconductor structure of claim 34, wherein the identifiable boundary is oriented parallel to at least one of the active surface and the back surface.
